(19) United States
(12) Patent Application Publication
(10) Pub. No.: US 2023/0187342 A1
(43) Pub. Date: Jun. 15, 2023

(54) DOPANT-FREE INHIBITOR FOR AREA SELECTIVE DEPOSITIONS

(71) Applicant: International Business Machines Corporation, Armonk, NY (US)

(72) Inventors: Nicholas Anthony Lanzillo, Wynantskill, NY (US); PRASAD BHOSALE, Albany, NY (US); Alexander Edward Hess, Redwood Estates, CA (US); SON NGUYEN, Schenectady, NY (US); Rudy J. Wojtecki, San Jose, CA (US)

(21) Appl. No.: 17/547,669

(22) Filed: Dec. 10, 2021

(51) Int. Cl. H01L 23/522; H01L 21/768; H01L 21/3105

(52) U.S. Cl. CPC H01L 23/5226; H01L 21/76897; H01L 21/76879; H01L 21/31053; H01L 21/76883

(57) ABSTRACT

A method of forming a fully-aligned via (FAV) structure is provided. The method includes arranging conductive material adjacent to a dielectric pad and chemically deactivating a surface of the conductive material by forming a dopant-free surface-aligned monolayer (SAM) thereon. Dielectric material is deposited onto the dielectric pad aside the dopant-free SAM and the dopant-free SAM is removed from the surface of the conductive material.

### BACKGROUND

The present invention generally relates to semiconductor devices, and more specifically, to improving semiconductor device fabrication using dopant-free inhibitors for area selective depositions for creating fully aligned vias (FAVs).

Integrated circuits commonly include electrically conductive microelectronic structures, known as vias, to electrically connect metal lines or other interconnects above the vias to metal lines or other interconnects below the vias. Vias are usually formed by a lithographic process. Representatively, a photoresist layer can be spin coated over a dielectric layer, the photoresist layer can be exposed to patterned actinic radiation through a patterned mask and then the exposed layer can be developed in order to form an opening in the photoresist layer. An opening for the via can be etched in the dielectric layer by using the opening in the photoresist layer as an etch mask. This opening is referred to as a via opening. The via opening can be filled with one or more metals or other conductive materials to form a metal-filled via.

### SUMMARY

Embodiments of the present invention are directed to a method of forming a fully-aligned via (FAV) structure. A non-limiting example of the method includes arranging conductive material adjacent to a dielectric pad and chemically deactivating a surface of the conductive material by forming a dopant-free surface-aligned monolayer (SAM) thereon. Dielectric material is deposited onto the dielectric pad aside the dopant-free SAM and the dopant-free SAM is removed from the surface of the conductive material.

Embodiments of the present invention are directed to a method of forming a fully-aligned via (FAV) structure. A non-limiting example of the method includes arranging metal between dielectric pads, chemically deactivating a surface of the metal by forming a dopant-free surface-aligned monolayer (SAM) comprising hydroxamic acid thereon, depositing, by chemical vapor deposition (CVD), a low-k dielectric material onto the dielectric pads at opposite sides of the dopant-free SAM and removing the dopant-free SAM from the surface of the metal to form the FAV.

Embodiments of the invention are directed to a fully-aligned via (FAV) precursor structure. A non-limiting example of the FAV precursor structure includes conductive material arranged adjacent to a dielectric pad and a dopant-free surface-aligned monolayer (SAM) formed on a surface of the conductive material to chemically deactivate the surface of the conductive material.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 is a flow diagram illustrating a method of forming a fully-aligned via (FAV) structure in accordance with one or more embodiments of the present invention;

FIG. 2 is a flow diagram illustrating a method of forming a FAV structure in accordance with one or more embodiments of the present invention;

FIG. 3 is a schematic side-view of conductive material arranged between dielectric pads in accordance with one or more embodiments of the present invention;

FIG. 4 is a schematic side-view of a dopant-free SAM formed on the conductive material of FIG. 3 in accordance with one or more embodiments of the present invention;

FIG. 5 is a schematic side-view of additional SAMs formed on the dopant-free SAM of FIG. 4 to form a stack in accordance with one or more embodiments of the present invention;

FIG. 6 is a schematic side-view of pillars of dielectric material formed on opposite sides of the stack of FIG. 5 with a bridge structure of the dielectric material formed over the stack of FIG. 5 in accordance with one or more embodiments of the present invention

FIG. 7 is a schematic side-view of an FAV precursor structure with remainders of the pillars of FIG. 6 on opposite sides of the stack or a remainder of the stack of FIG. 6 in accordance with one or more embodiments of the present invention;

FIG. 8 is a schematic side-view of an FAV structure with the stack or the remainder of the stack of FIG. 7 removed in accordance with one or more embodiments of the present invention; and

FIG. 9 is a schematic perspective view of subsequent processing operations to form a contact with the FAV structure of FIG. 8 in accordance with one or more embodiments of the present invention.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the disclosed embodiments, the various elements illustrated in the figures are provided with two or three digit reference numbers. With minor exceptions, the leftmost digit(s) of each reference number correspond to the figure in which its element is first illustrated.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the invention, fully-aligned via (FAV) topography is often required at tight pitches to ensure sufficient margin between a contact, which is disposed in electrical contact with a first metallization interconnect, and a second metallization contact adjacent to the first metallization contact. Typically, FAV topography is achieved by metal recess processes. However, it has been found that metal recess processes tend to introduce relatively large variability in certain line properties (e.g., resistance and capacitance or RC-delays) due to non-uniformities in recess depths.

Selective dielectric deposition has therefore been developed as an alternative to metal recess processes. Selective dielectric deposition generally requires a self-aligned deposition of an inhibitor on a metallic surface followed by chemical vapor deposition (CVD) or atomic layer deposition (ALD) and is less susceptible to swings in RC-delays from variations in film thicknesses as metal recess processes.

A problem with selective dielectric deposition is that achieving an FAV topography requires selective deposition of dielectric on a dielectric. This necessitates a protection of the metal surface and only organic monolayers provide an acceptable level of selectivity for a desired thickness of surface topography introduced in a self-aligned manner (e.g., selective adhesion to a metal surface). Unfortunately, introductions of surface materials or solutions (?) demonstrated in the literature typically rely on either phosphonic or thiol for selective adhesion and metal surfaces are often sensitive to impurities. The sensitivity of metal surfaces to impurities, such as phosphorous and thiols, results in such phosphorous and thiols being materials that can be difficult to fully remove from the metal surfaces after a selective deposition process and may subsequently present reliability issues. Furthermore, residual inhibiting material may be present on interlayer dielectric (ILD) surfaces.

Turning now to an overview of the aspects of the invention, one or more embodiments of the invention address the above-described shortcomings of the prior art by providing for growth of a low-k silicon oxycarbide (SiCOH) selectively on top of a dielectric. Successfully growing one type of dielectric on top of another type of dielectric has great potential for a variety of semiconductor applications, including the creation of fully aligned vias (FAVs). One issue with such growth is lateral deposition, which impacts the implementation of thicker selective dielectric growth. Therefore, long chain self-assembled monolayers or surface aligned monolayers (SAMs) with stable cross-linking are employed. By using long chain cross-linking surface SAMs bonded to a conductive surface or region, lateral growth can be successfully inhibited. Polymerization can occur by thermal and ultraviolet (UV) cure. The polymerization process can be triggered by a number of stimuli, including temperature. In one instance, a temperature of about 80-100° C. can start this polymerization process, if it is in an inert environment. The removal of the long chain SAM results in the formation of a selective FAV structure.

The above-described aspects of the invention address the shortcomings of the prior art by providing for SAMs that are dopant-free inhibitors for selective depositions. The dopant-free inhibitors provide for short exposure times leading to high static water contact angles (1 minute=107°) and selectivity for metal surfaces. The dopant-free inhibitors exhibit increased acidity, which increases binding energies to metal surfaces, and are effective at blocking certain ALD processes.

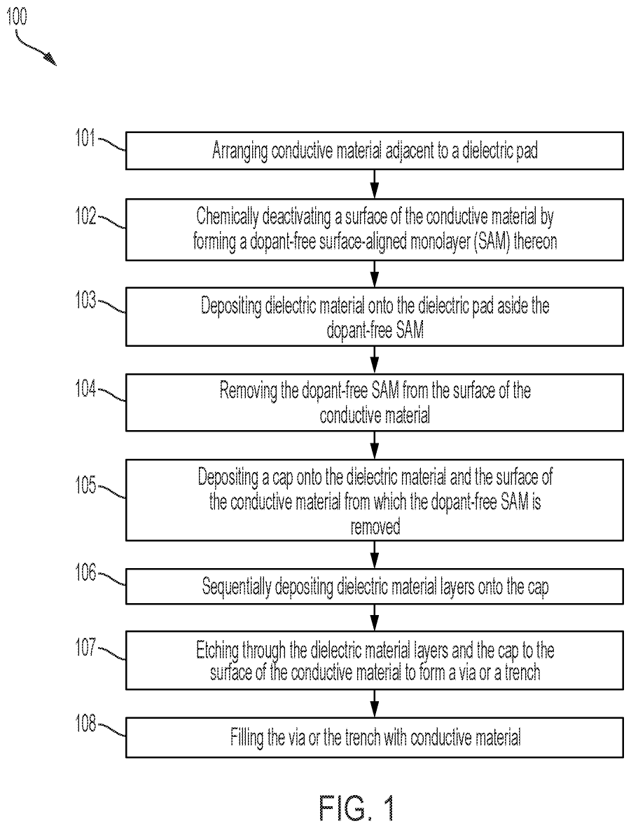

With reference to FIG. 1, a method 100 of forming a fully-aligned via (FAV) structure is provided. As shown in FIG. 1, the method 100 includes arranging conductive material adjacent to a dielectric pad (block 101) and chemically deactivating a surface of the conductive material by forming a dopant-free surface-aligned monolayer (SAM) thereon (block 102). Dielectric material is then deposited onto the dielectric pad aside the dopant-free SAM (block 103) and the dopant-free SAM is removed from the surface of the conductive material (block 104). The method 100 can further include depositing a cap onto the dielectric material and the surface of the conductive material from which the dopant-free SAM is removed (block 105), sequentially depositing dielectric material layers onto the cap (block 106), etching through the dielectric material layers and the cap to the surface of the conductive material to form a via or a trench (block 107) and filling the via or the trench with conductive material (block 108).

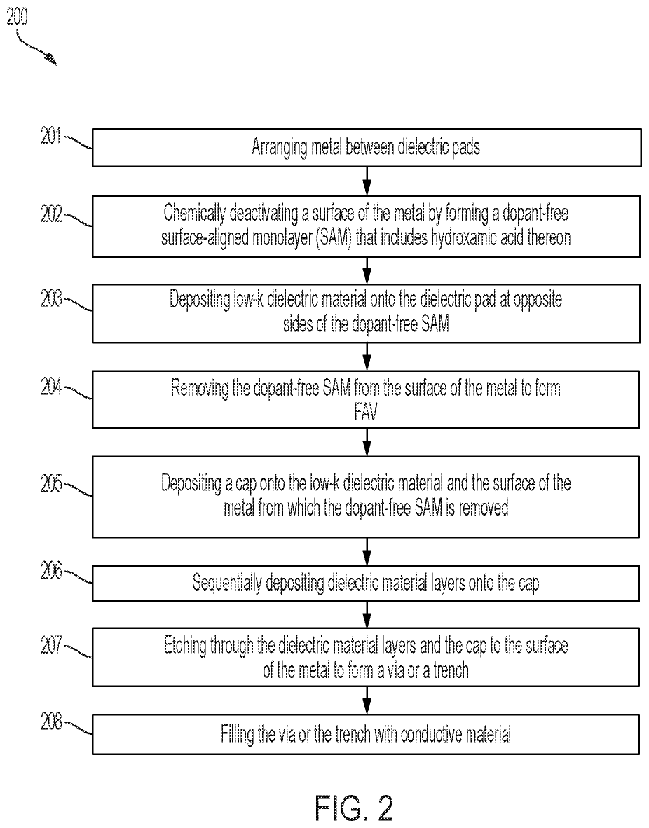

With reference to FIG. 2, a method 200 of forming a fully-aligned via (FAV) structure is provided. As shown in FIG. 2, the method 200 includes arranging metal between dielectric pads (block 201) and chemically deactivating a surface of the metal by forming a dopant-free surface-aligned monolayer (SAM) that includes hydroxamic acid thereon (block 202). A low-k dielectric material is then deposited, by chemical vapor deposition (CVD) or another similar process, onto the dielectric pads at opposite sides of the dopant-free SAM (block 203) and the dopant-free SAM is removed from the surface of the metal to form the FAV (block 204). The method 200 can further include depositing a cap onto the low-k dielectric material and the surface of the metal from which the dopant-free SAM is removed (block 205), sequentially depositing dielectric material layers onto the cap (block 206), etching through the dielectric material layers and the cap to the surface of the metal to form a via or a trench (block 207) and filling the via or the trench with conductive material (block 208).

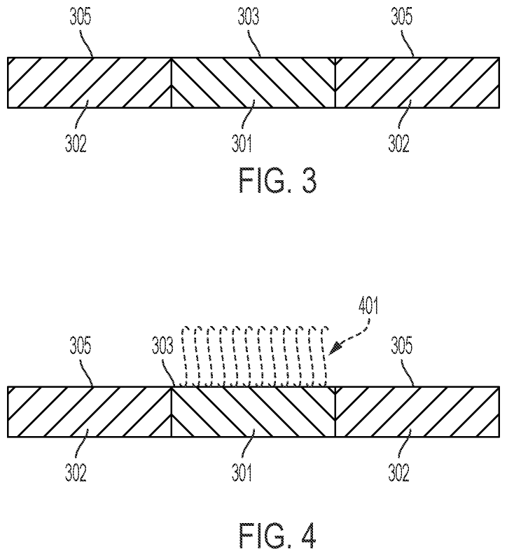

With reference to FIGS. 3-9, the methods of FIGS. 1 and 2 will be described in greater detail.

With reference to FIG. 3, conductive material 301 is arranged adjacent to a dielectric pad, which can be provided as first and second dielectric pads 302 with the conductive material 301 arranged between them. The following description will thus relate to the case of the conductive material 301 being arranged between the first and second dielectric pads 302. This is done for clarity and brevity and is not intended to otherwise limit the scope of the disclosure. The conductive material 301 has a conductive surface 303 and the first and second dielectric pads 302 each have a dielectric surface 305 that is adjacent to and coplanar with the conductive surface 303.

With reference to FIG. 4, the conductive surface 303 of the conductive material 301 is deactivated by the forming of a dopant-free surface-aligned monolayer (SAM) 401 thereon. This can be accomplished by CVD processing or another similar process.

In accordance with one or more embodiments of the present invention, the conductive material 301 includes metal and the dopant-free SAM 401 is configured to resist formation of sulfuric, phosphoric and boric acids upon exposure to moisture which can then react with the metal of the conductive material 301. Thus, the dopant-free SAM 401 can include a head group lacking sulfur, phosphorous and boron. The dopant-free SAM 401 should also include a head group lacking flourine, chlorine and indium due to potential for corrosion with the metal of the conductive surface 303. In addition, the dopant-free SAM 401 should also include a head group lacking arsenic, aluminum and selenium, which are less reactive and more benign than the other potential dopants listed above, but which should still be avoided. In some cases, the dopant-free SAM 401 can include a head group that includes a carbon-flourine (C—F) group.

With the dopant-free SAM 401 provided without the dopants listed above (i.e., sulfur, phosphorous, boron, flourine, chlorine, indium, arsenic, aluminum and selenium and combinations thereof), the dopant-free SAM 401 offers certain advantages. Sulfur and phosphorous, in particular, can react readily with metal, especially in the presence of moisture to form sulfur-based and phosphoric-based acids that can subsequently degrade the metal and consequently degrade its resistance and stability during fabrication. Indeed, even if surface layers of sulfur and phosphorus can be removed, very small amounts of sulfur and phosphorous may remain in the metal after fabrication and even these small amounts can degrade the metal during operations. Providing the dopant-free SAM 401 avoids the possibility of even small amounts of such dopants to invade and degrade the metal of the conductive material 301.

As an example, the dopant-free SAM 401 can include hydroxamic acid. More generally, the dopant-free SAM 401 can be provided as a terminal n-hydroxamic acid in its head group and a long chain aliphatic compound with the following structure, which can produce a stable solution in 4-methyl-2-pentanol for example.

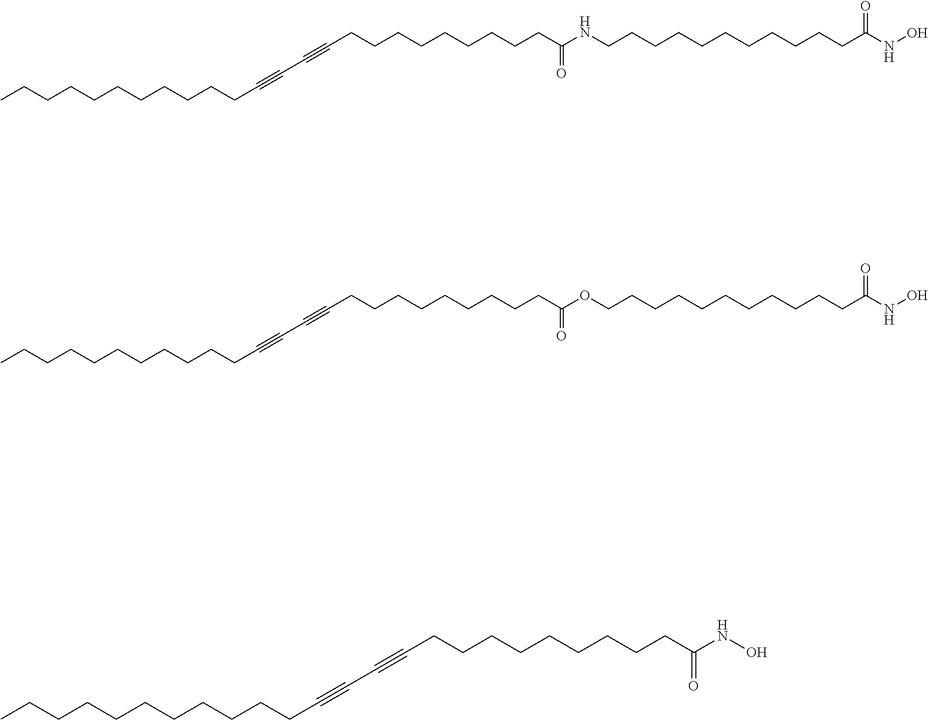 [SMILES: CCCCCCCCCCCC#CC#CCCCCCCCCCC(=O)NCCCCCCCCCCCC(=O)NO ; CCCCCCCCCCCC#CC#CCCCCCCCCCC(=O)OCCCCCCCCCCCC(=O)NO ; CCCCCCCCCCCC#CC#CCCCCCCCCCC(=O)NO]

The use of hydroxamic acids and other similar compounds is helpful in forming the sought-after FAV. This is because hydroxamic acids can acts an inhibiting material that chemically deactivates the conductive surface 303 of the conductive material 301 for an area selective deposition of a dielectric material, such as a low-k dielectric material, during a CVD process.

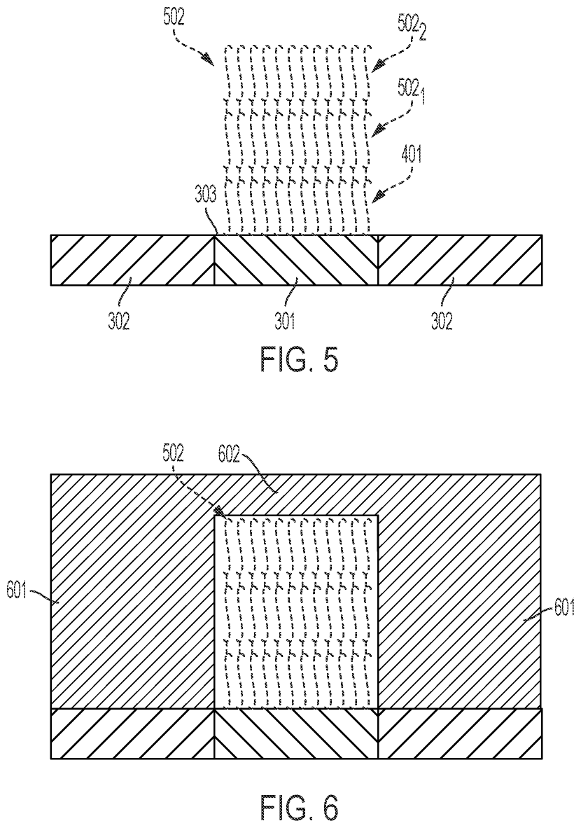

With reference to FIG. 5, additional SAMs 501 can be deposited onto the dopant-free SAM 401 to form a stack 502. In these cases, the dopant-free SAM 401 and the additional SAMs 501 can be bonded to one another by at least one of thermal and ultraviolet (UV) curing to form cross-linked bonds and other similar types of bonds between adjacent molecules of the dopant-free SAM 401 and the additional SAMs 501.

In accordance with embodiments, the additional SAMs 501 can have similar chemical structures as the dopant-free SAM 401. Alternatively, the additional SAMs 501 can have unique or progressively unique chemical structures. For example, a first layer 502₁ of the stack 502 above the dopant-free SAM 401 can include some dopants which are less reactive and slightly more benign than phosphorous and sulfur, such as arsenic, aluminum and selenium, and a second layer 502₂ of the stack 502 above the first layer 502₁ can include dopants, such as phosphorous and sulfur, because these dopants will not touch or otherwise come into contact with the metal of the conductive material 301.

The following description will relate to those cases where additional SAMs 501 are deposited onto the dopant-free SAM 401 to form the stack 502. In these cases, the additional SAMs 501 can have variable chemical structures.

With reference to FIG. 6, dielectric material is deposited onto the first and second dielectric pads 302 at opposite sides of the stack 502 of the dopant-free SAM 401 and the additional SAMs 501 by CVD processing or other similar processes. The dielectric material can thus be built up into pillars 601 on either side of the stack 502 and then into a bridge structure 602 that crosses over the stack 502.

In accordance with embodiments, the first and second dielectric pads 302 can be formed of an interlayer dielectric (ILD), such as ultra low-k SiCOH or other similar materials, and the dielectric material deposited into the first and second dielectric pads 302 can be formed of SiCOH, low-k SiCOH or other similar materials.

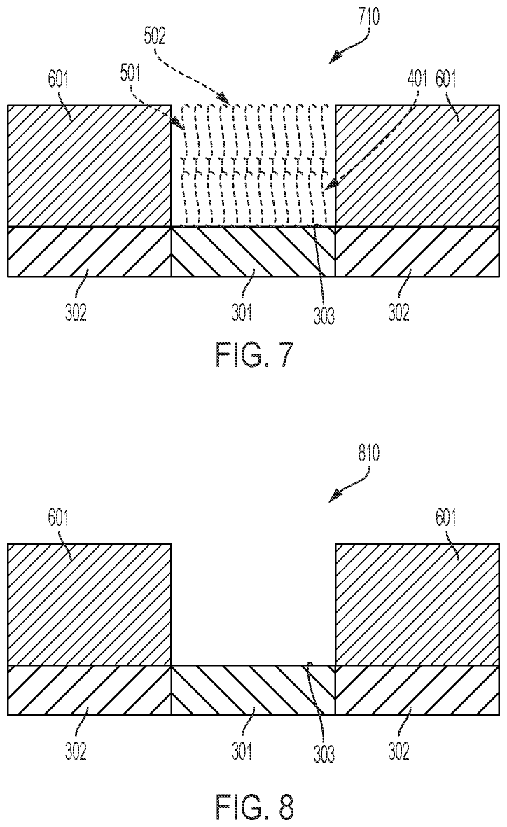

With reference to FIG. 7, the dielectric material of the bridge structure 602 and the pillars 601 is removed by chemical mechanical polishing (CMP) or other similar processes to be planarized with the stack 502. In some cases, one or more layers of the stack 502 are also removed, in which case the remainders of the pillars 601 and a remainder of the stack 502 are planarized. The resulting structure is provided as an FAV precursor structure 710 that includes the conductive material 301 arranged adjacent to the first and second dielectric pads 302, at least the dopant-free SAM 401 formed on the conductive surface 303 of the conductive material 301 to chemically deactivate the conductive surface 303 (and, optionally, the additional SAMs 501) and the remainders of the pillars 601.

With reference to FIG. 8, the stack 502 or the remainder of the stack 502 is removed by etching, such as an H₂ plasma etching. Thus, an FAV structure 810 is formed and includes the conductive material 301 arranged adjacent to the first and second dielectric pads 302 and the remainders of the pillars 601. The conductive surface 303 of the conductive material 301 is exposed and available for contact with a contact (see below) and, due to the use of the dopant-free SAM 401, the conductive material 301 is free or substantially free of dopants which would otherwise degrade its resistive and reliability characteristics. Moreover, because the dopant-free SAM 401 and the additional SAMs 501 in the stack 502 effectively prevent growth by lateral deposition of the dielectric material of the pillars 601, the FAV structure 810 exhibits the potential for correct contact placement (see below).

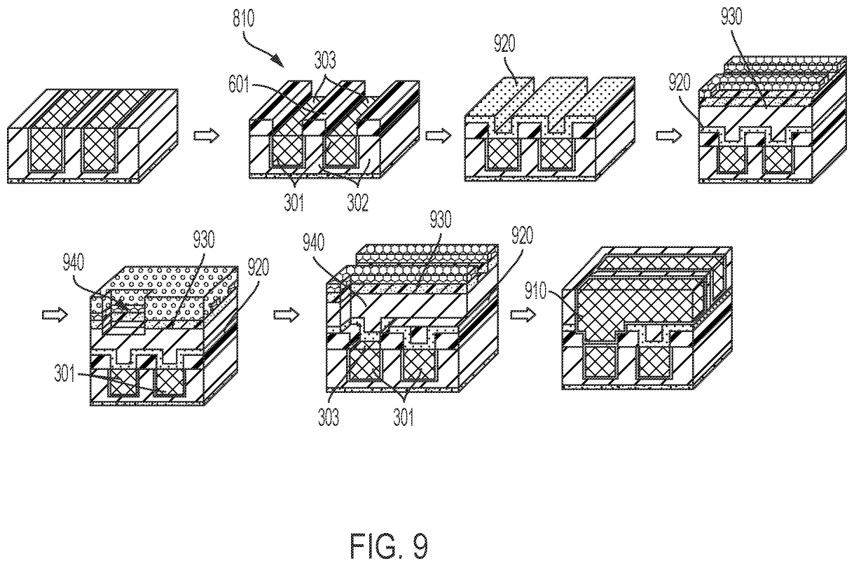

With reference to FIG. 9, subsequent processing operations will now be described for forming a contact 910 that is correctly placed in contact with the conductive surface 303 of the conductive material 301 of the FAV structure 810. These subsequent processing operations include depositing a cap 920 onto the dielectric material of the remainders of the pillars 601 and the conductive surface 303 and then sequentially depositing dielectric material layers 930 onto the cap 920. Next, etch processing through the dielectric material layers 930 and the cap 920 and to the conductive surface 303 is performed to form a via and/or a trench 940. The via and/or the trench 940 is subsequently filled with conductive material of the contact 910, which is thus disposed in electrical communication with the conductive surface 303.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method of forming a fully-aligned via (FAV) structure, the method comprising:
arranging conductive material adjacent to a dielectric pad;
chemically deactivating a surface of the conductive material by forming a dopant-free surface-aligned monolayer (SAM) thereon;
depositing dielectric material onto the dielectric pad aside the dopant-free SAM; and
removing the dopant-free SAM from the surface of the conductive material.

2. The method according to claim 1, wherein the chemically deactivating of the surface of the conductive material comprises depositing the dopant-free SAM thereon by chemical vapor deposition (CVD).

3. The method according to claim 1, wherein the depositing of the dielectric material comprises:
forming a pillar of the dielectric material aside the dopant-free SAM; and
planarizing the pillar of the dielectric material and the dopant-free SAM.

4. The method according to claim 1, wherein the removing of the dopant-free SAM from the surface of the conductive material comprises etching the dopant-free SAM.

5. The method according to claim 1 further comprising:
depositing additional SAMs onto the dopant-free SAM; and
bonding the dopant-free SAM and the additional SAMs to one another by at least one of thermal and ultraviolet (UV) curing.

6. The method according to claim 1, wherein the conductive material comprises metal and the dopant-free SAM resists formation of sulfuric, phosphoric and boric acids that react with the metal.

7. The method according to claim 1, wherein the dopant-free SAM comprises hydroxamic acid.

8. The method according to claim 1, wherein the dopant-free SAM comprises one of:
a head group lacking sulfur, phosphorous and boron, along with flourine, chlorine, indium, arsenic, aluminum and selenium; and
a head group comprising a carbon-flourine (C—F) group.

9. The method according to claim 1 further comprising:
depositing a cap onto the dielectric material and the surface of the conductive material from which the dopant-free SAM is removed;
sequentially depositing dielectric material layers onto the cap;
etching through the dielectric material layers and the cap to the surface of the conductive material to form a via or a trench; and
filling the via or the trench with conductive material.

10. A method of forming a fully-aligned via (FAV) structure, the method comprising:
arranging metal between dielectric pads;
chemically deactivating a surface of the metal by forming a dopant-free surface-aligned monolayer (SAM) comprising hydroxamic acid thereon;
depositing, by chemical vapor deposition (CVD), a low-k dielectric material onto the dielectric pads at opposite sides of the dopant-free SAM; and
removing the dopant-free SAM from the surface of the metal to form the FAV.

11. The method according to claim 10 further comprising:
depositing a cap onto the low-k dielectric material and the surface of the metal from which the dopant-free SAM is removed;
sequentially depositing dielectric material layers onto the cap;
etching through the dielectric material layers and the cap to the surface of the metal to form a via or a trench; and
filling the via or the trench with conductive material.

12. A fully-aligned via (FAV) precursor structure comprising:
conductive material arranged adjacent to a dielectric pad; and
a dopant-free surface-aligned monolayer (SAM) formed on a surface of the conductive material to chemically deactivate the surface of the conductive material.

13. The FAV precursor structure according to claim 12 further comprising a pillar of dielectric material formed on the dielectric pad aside the dopant-free SAM.

14. The FAV precursor structure according to claim 13, wherein the pillar of the dielectric material and the dopant-free SAM are planarized.

15. The FAV precursor structure according to claim 12 further comprising additional SAMs formed on the dopant-free SAM.

16. The FAV precursor structure according to claim 15, wherein the dopant-free SAM and the additional SAMs are bonded.

17. The FAV precursor structure according to claim 15, wherein the additional SAMs comprise dopants.

18. The FAV precursor structure according to claim 12, wherein the conductive material comprises metal and the dopant-free SAM resists formation of sulfuric, phosphoric and boric acids that react with the metal.

19. The FAV precursor structure according to claim 12, wherein the dopant-free SAM comprises hydroxamic acid.

20. The FAV precursor structure according to claim 12, wherein the dopant-free SAM comprises one of:
a head group lacking sulfur, phosphorous and boron, along with flourine, chlorine, indium, arsenic, aluminum and selenium; and
a head group comprising a carbon-flourine (C—F) group.
